(19) United States
(12) Patent Application Publication
(10) Pub. No.: US 2026/0088062 A1
(43) Pub. Date: Mar. 26, 2026

(54) FERROELECTRIC MEMORY DEVICE

(71) Applicant: SAMSUNG ELECTRONICS CO., LTD., SUWON-SI (KR)

(72) Inventors: Sunggyeong Lee, Suwon-si (KR); Changyoung Lee, Suwon-si (KR); HYUN-CHUL YOON, Suwon-si (KR)

(21) Appl. No.: 19/263,722

(22) Filed: Jul. 9, 2025

(30) Foreign Application Priority Data
Sep. 25, 2024 (KR) 10-2024-0130277

(51) Int. Cl. G11C 5/06; G11C 11/22

(52) U.S. Cl. CPC G11C 5/063; G11C 11/221; G11C 11/2257; G11C 11/2273; G11C 11/2275

(57) ABSTRACT

A ferroelectric memory device includes a ferroelectric memory cell connected between a bit line and a plate line and controlled by a word line, a row decoder configured to activate the word line, a plate line voltage generator configured to provide a ground voltage to the plate line during a precharge period and provide a first voltage to the plate line in response to the activation of the word line, and a sense amplifier configured to amplify a voltage of the bit line to a second voltage that is higher than the first voltage during a sensing operation.

### CROSS-REFERENCE TO RELATED APPLICATION

This application claims priority under 35 U.S.C. § 119 to Korean Patent Application No. 10-2024-0130277, filed on Sep. 25, 2024 in the Korean Intellectual Property Office, the entire disclosure of which is incorporated by reference herein in its entirety.

### TECHNICAL FIELD

The present disclosure relates to a ferroelectric memory device.

### DISCUSSION OF THE RELATED ART

Ferroelectric memory devices usually have non-volatile memory characteristics because ferroelectric capacitors are used as ferroelectric memory cells of the ferroelectric memory devices. However, unlike other non-volatile memory devices such as flash memory devices, the ferroelectric memory devices may be implemented in structures similar to volatile memory devices such as dynamic random access memory (DRAM) devices in which random access for each memory cell is possible. Therefore, the ferroelectric memory devices may take both advantages of the non-volatile memory devices and the volatile memory devices, in which the ferroelectric memory devices may feature relatively superior read and write performance to other non-volatile devices, while retaining their stored data even when power supplies for the ferroelectric memory devices are turned off.

However, the ferroelectric memory devices may require high voltages during the read and write operation because the ferroelectric capacitors require relatively high voltages to be polarized effectively. The ferroelectric memory devices may include the ferroelectric memory cells between plate lines and bit lines, and apply cell voltages across the ferroelectric capacitors. The applied cell voltages between the plate line and the bit line may be different depending on whether the ferroelectric memory devices are in a standby mode, or in read or write operations. During the write operation, the ferroelectric memory devices may perform a rewrite operation and a write operation after a sensing operation in a branched manner depending on the data value stored in the ferroelectric capacitors. The branching between the rewrite operation and the write operation may require additional time and may increase the write operation time for the ferroelectric memory cell and degrade overall performance of the ferroelectric memory devices.

### SUMMARY

A ferroelectric memory device includes a ferroelectric memory cell which includes a cell transistor and a ferroelectric capacitor connected in series between a bit line and a plate line, and the cell transistor being controlled by a word line, a row decoder configured to activate the word line upon receiving a row activation command, a plate line voltage generator configured to provide a ground voltage to the plate line in a precharged state, and to provide a first voltage to the plate line upon receiving the row activation command, and a sense amplifier configured to perform a sensing operation in response to the row activation command, wherein the sense amplifier amplifies a voltage of the bit line to one of a ground voltage and a second voltage depending on the stored data in the ferroelectric capacitor, in which the second voltage is higher than the first voltage.

A ferroelectric memory device includes a ferroelectric memory cell including a cell transistor and a ferroelectric capacitor connected in series between a bit line and a plate line, and the cell transistor is controlled by a word line, a row decoder configured to activate the word line upon receiving a row activation command, a plate line voltage generator configured to provide a first voltage to the plate line upon receiving the row activation command, and provide a ground voltage to the plate line upon receiving a precharge command, and a sense amplifier configured to provide the ground voltage to the bit line upon receiving the precharge command, wherein, after a precharge operation being performed in response to the precharge command, the ferroelectric capacitor remains as polarized in one of a first direction and a second direction depending on the data stored in the ferroelectric capacitor.

A ferroelectric memory device includes a ferroelectric memory cell including a cell transistor and a ferroelectric capacitor connected in series between a bit line and a plate line, and the cell transistor being controlled by a word line, a row decoder configured to activate the word line upon receiving a row activation command, a plate line voltage generator configured to provide a first voltage to the plate line upon receiving the row activation command, and a write driver, in response to a write command, configured to drive a voltage of the bit line to one of a ground voltage and a second voltage, in which the second voltage is higher than the first voltage.

A method for operating a ferroelectric memory device comprises activating a word line upon receiving a row activation command, applying a first voltage to a plate line upon receiving the row activation command, in which the first voltage is generated by a plate line voltage generator, and performing a sensing operation in response to the row activation command by a sense amplifier, in which the sense amplifier amplifies a voltage of the bit line to one of a ground voltage and a second voltage depending on the stored data in a ferroelectric memory cell of the ferroelectric memory device, in which the second voltage is higher than the first voltage.

### BRIEF DESCRIPTION OF THE DRAWINGS

FIG. 1 is a block diagram showing a memory system according to an embodiment.

FIG. 2 is a block diagram showing a ferroelectric memory device according to an embodiment.

FIG. 3 is a circuit diagram showing an example of the ferroelectric memory cell of FIG. 2.

FIG. 4 is a hysteresis curve for illustrating an operation of a ferroelectric memory cell according to an embodiment.

FIG. 5 to FIG. 6 are drawings for illustrating a write operation of a ferroelectric memory cell according to an embodiment.

FIG. 7 to FIG. 8 are drawings for illustrating a read operation of a ferroelectric memory cell according to an embodiment.

FIG. 9 is a voltage graph for illustrating a charge sharing period within a read operation of a ferroelectric memory cell according to an embodiment.

FIG. 10 is a drawing for illustrating a bank array according to an embodiment.

FIG. 11 is a timing diagram for illustrating a read operation of a ferroelectric memory cell.

FIG. 12 is a timing diagram for illustrating a read operation of a ferroelectric memory cell.

FIG. 13 is a timing diagram for illustrating a write operation of a ferroelectric memory cell.

FIG. 14 is a timing diagram for illustrating a write operation of a ferroelectric memory cell.

FIG. 15 is a circuit diagram showing an example of the ferroelectric memory cell of FIG. 2.

FIG. 16 is a drawing for illustrating a bank array according to an embodiment.

FIG. 17 is a block diagram showing an electronic device according to an embodiment.

### DETAILED DESCRIPTION OF THE EMBODIMENTS

Hereinafter, ferroelectric memory devices in accordance with embodiments will be described in more detail with reference to the accompanying drawings. The described embodiments may be modified in various different ways without departing from the spirit or scope of the present disclosure.

The same reference numerals are used for the same components in the drawings.

Unless explicitly described to the contrary, the word “comprise,” and variations such as “comprises” or “comprising”, will be understood to imply the inclusion of stated elements but not the exclusion of any other elements.

Specific numbers described in a claim, even if explicitly recited within the claim, should not be construed as limiting the specific numbers in other claims where such citation does not exist. For example, the introductory phrases “at least one” and “one or more” used in claims should not be understood differently by the “one” described in different claims.

The phrase “at least one of A, B, and C” is intended to include all possible combination of A, B and C. For example, “a system having at least one of A, B, and C” would include that the system may have A alone, B alone, C alone, A and B together, A and C together, B and C together, or A, B, and C together. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include “A” or “B” only, or “A and B.”

The terms “a module,” “a unit,” or “a part” indicates a function block, in which at least one function or operation is performed, and may be realized as hardware or software, or a combination thereof.

According to an embodiment, a ferroelectric memory device includes a ferroelectric memory cell which includes a cell transistor and a ferroelectric capacitor connected in series between a bit line and a plate line, and the cell transistor being controlled by a word line, a row decoder configured to activate the word line upon receiving a row activation command, a plate line voltage generator configured to provide a ground voltage to the plate line in a precharged state, and to provide a first voltage to the plate line upon receiving the row activation command, and a sense amplifier configured to perform a sensing operation in response to the row activation command, wherein the sense amplifier amplifies a voltage of the bit line to one of a ground voltage and a second voltage depending on the stored data in the ferroelectric capacitor, in which the second voltage is higher than the first voltage

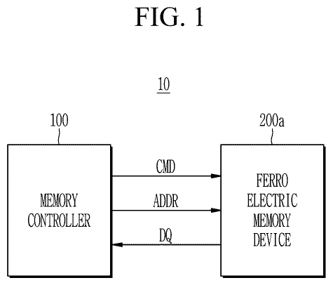

FIG. 1 is a block diagram showing a memory system according to an embodiment.

Referring to FIG. 1, a memory system 10 may include a memory controller 100 and a ferroelectric memory device 200a. The memory controller 100 may control overall operation of the memory system 10. For example, the memory controller 100 may issue a write command for the ferroelectric memory device 200a to perform a write operation in which write data are written into the ferroelectric memory device 200a, or may issue a read command for the ferroelectric memory device 200a to perform a read operation in which read data are sensed from the ferroelectric memory device 200a. The memory controller 100 is further connected to a host device, and issues the write or read command in response to requests from the host device.

More particularly, the memory controller 100 may provide command signals CMD and address signals ADDR to the ferroelectric memory device 200a, and may control a data exchange operation of the ferroelectric memory device 200a. For example, the command signals CMD may include signals for activating a word line of the ferroelectric memory device 200a and/or for performing write or read operation with respect to the activated word line. The memory controller 100 may exchange data DQ with the ferroelectric memory device 200a.

The ferroelectric memory device 200a may be a ferroelectric random-access memory (FeRAM) device including ferroelectric memory cells. Hereinafter, the ferroelectric random-access memory (FeRAM) device is simply referred to as a FeRAM. The FeRAM may have non-volatile memory characteristics, in which data are stored in ferroelectric memory cells based on polarization state of a ferroelectric capacitor within each of the ferroelectric memory cells. The FeRAM is different from a volatile memory device such as DRAM in that the FeRAM has non-volatile characteristics, thereby maintains data even when power supply for the ferroelectric memory device 200a is turned off, and does not require a refresh operation.

The ferroelectric memory cell of the ferroelectric memory device 200a may store one-bit data, in which the ferroelectric memory cell stores one of two logic states, one of which is logic high “1” and the other is logic low “0.” The ferroelectric memory device 200a may perform a write or read operation by accessing a bank, a row, and a column of the ferroelectric memory device 200a based on the address signals ADDR. The ferroelectric memory device 200a may perform random access operation because the ferroelectric memory device 200a may be implemented in an architecture of the volatile RAM such as DRAM.

Since the ferroelectric memory device 200a has the destructive readout characteristic with respect to the ferroelectric memory cell, when a sensing operation is performed with respect to the ferroelectric memory cell, a rewrite operation for restoring data may be accompanied.

Because relatively high voltage is required for polarization of the ferroelectric capacitor, a cell voltage applied across the ferroelectric capacitor is usually higher than a cell voltage applied to the memory cell capacitor of the volatile memory device such as DRAM. The ferroelectric memory device 200a may apply a plate line voltage to the plate line which is an electrode of the ferroelectric capacitor, and apply a bit line voltage to the bit line for providing an effective polarization bias to the ferroelectric capacitor. The voltages applied to the plate line and the bit line may be different depending on the operation mode of the FeRAM.

Unlike DRAM device in which a fixed voltage is applied to the plate line regardless of operations performed on the DRAM device, the plate line voltage applied to the ferroelectric memory device 200a may be different depending on the operation mode performed by the ferroelectric memory device 200a. According to an embodiment, the ferroelectric memory device 200a may have high power efficiency and operating speed by applying different plate line voltages to the plate line compared with other memory devices which applies fixed plate line voltages to the plate lines.

Although the memory system 10 shown in FIG. 1 includes a single ferroelectric memory device 200a and the memory controller 100 connected to the single ferroelectric memory device 200a, the memory controller 100 may be connected to a plurality of ferroelectric memory devices.

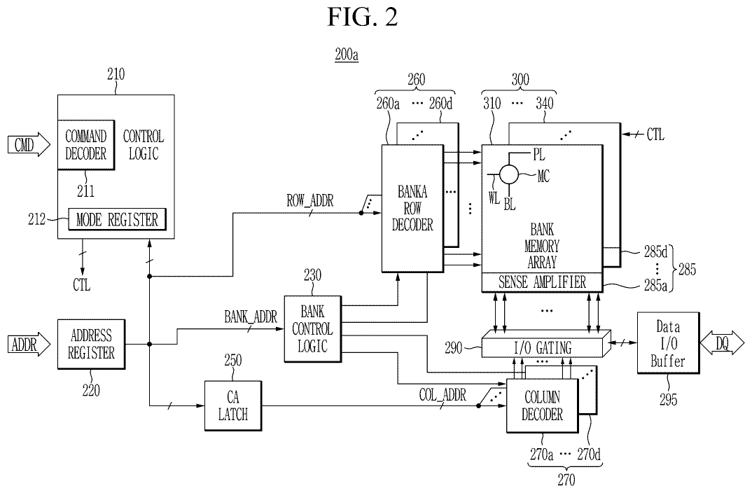

FIG. 2 is a block diagram showing the ferroelectric memory device according to an embodiment.

Referring to FIG. 2, the ferroelectric memory device 200a may include a control logic 210, an address register 220, a bank control logic 230, a column address latch 250, a row decoder 260, a column decoder 270, a memory cell array 300, a sense amplifier unit 285, an input/output gating circuit 290, and a data input/output buffer 295.

The memory cell array 300 may include first to fourth bank arrays 310 to 340. In addition, the row decoder 260 may include first to fourth bank row decoders 260a to 260d connected to the first to fourth bank arrays 310 to 340 respectively, the column decoder 270 may include first to fourth bank the column decoders 270a to 270d connected to the first to fourth bank arrays 310 to 340 respectively, and the sense amplifier unit 285 may include first to fourth bank sense amplifiers 285a to 285d connected to the first to fourth bank arrays 310 to 340 respectively.

The first to fourth bank arrays 310 to 340, the first to fourth bank sense amplifiers 285a to 285d, the first to fourth bank column decoders 270a to 270d and the first to fourth bank row decoders 260a to 260d may configure first to fourth banks respectively. Each of the first to fourth bank arrays 310 to 340 may include a plurality of word lines WL, a plurality of bit lines BL, a plurality of ferroelectric memory cells MC, and a plurality of plate lines PL. The plurality of ferroelectric memory cells MC are formed at points where the word line WL and the bit line BL intersect each other.

Although FIG. 2 illustrates an example of the ferroelectric memory device 200a including four banks, the ferroelectric memory device 200a may include different number of banks. For example, the ferroelectric memory device 200a may include eight banks, sixteen banks or thirty two banks.

The address register 220 may receive an address ADDR including a bank address BANK_ADDR, a row address ROW_ADDR and a column address COL_ADDR from the memory controller 100. The address register 220 may provide the received bank address BANK_ADDR to the bank control logic 230, may provide the received row address ROW_ADDR to a row address decoder 260, and may provide the received column address COL_ADDR to the column address latch 250.

The bank control logic 230 may generate bank control signals in response to the bank address BANK_ADDR. Upon being selected by the bank address BANK_ADDR and the generated bank control signals, a bank row decoder corresponding to the bank address BANK_ADDR among the first to fourth bank row decoders 260a to 260d may be activated, and a bank column decoder corresponding to the bank address BANK_ADDR among the first to fourth bank column decoders 270a to 270d may be activated.

The bank row decoder activated by the bank control logic 230 among the first to fourth bank row decoders 260a to 260d may decode the row address ROW_ADDR received from the address register 220 to activate the word line WL corresponding to the row address ROW_ADDR. For example, the activated bank row decoder may apply a word line driving voltage to the word line WL corresponding to the row address.

The column address latch 250 may receive the column address COL_ADDR from the address register 220, and may store the received column address COL_ADDR. The column address latch 250 may gradually increase the received column address COL_ADDR for a burst mode operation. The column address latch 250 may apply the received and increased column address COL_ADDR to one of the first to fourth bank column decoders 270a to 270d selected by the bank address BANK_ADDR for read or write operation.

The bank column decoder activated by the bank control logic 230 among the first to fourth bank column decoders 270a to 270d may activate a sense amplifier corresponding to the bank address BANK_ADDR and the column address COL_ADDR through the input/output gating circuit 290.

The input/output gating circuit 290 may include an input data mask logic, read data latches for storing data output from the first to fourth bank arrays 310 to 340, write drivers for writing data to the first to fourth bank arrays 310 to 340, and circuits for gating input/output data.

The data DQ to be read from one bank array among the first to fourth bank arrays 310 to 340 may be detected by a sense amplifier corresponding to the one bank array, and may be stored in the read data latches. The data DQ stored in the read data latches may be provided to the memory controller 100 through the data input/output buffer 295. The data DQ to be written in one bank array among the first to fourth bank arrays 310 to 340 may be provided from the memory controller 100 to the data input/output buffer 295. The data DQ provided in the data input/output buffer 295 may be written in the one bank array through the write drivers. Hereinafter, the data DQ to be read from the bank arrays are referred to as “read data,” and the data DQ to be written into the bank arrays are referred to as “write data.”

The control logic 210 may control the operation of the ferroelectric memory device 200a. For example, the control logic 210 may generate the control signals CTL for the ferroelectric memory device 200a to perform the write or the read operation. The control logic 210 may include a command decoder 211 configured to decode a command CMD received from the memory controller 100 configured to set an operation mode of the ferroelectric memory device 200a. For example, the command decoder 211 may decode a write enable signal WE, a row address strobe signal RAS, a column address strobe signal CAS, a chip selection signal CS, or the like, and generate the control signals CTL corresponding to the command CMD. The control logic 210 may further include a mode register 212. The mode register 212 may be programed by the mode register set (MRS) command, and may be programmed with user-defined values. The mode register 212 may generate a corresponding mode signal depending on the programed operation mode.

The ferroelectric memory device 200a may further include a plate line voltage generator configured to provide a plate line voltage to the plurality of plate lines PL.

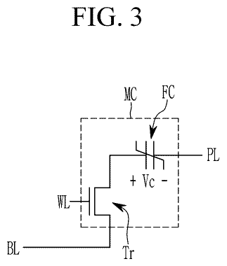

FIG. 3 is a circuit diagram showing an example of the ferroelectric memory cell of FIG. 2.

Referring to FIG. 3, the ferroelectric memory cell MC may include a cell transistor Tr and a ferroelectric capacitor FC. The cell transistor Tr and the ferroelectric capacitor FC may be coupled in series between the bit line BL and the plate line PL.

The cell transistor Tr may be connected to the word line WL through a gate terminal which is a control terminal, and may be turned on in response to an activation of the word line WL. A first terminal of the cell transistor Tr may be connected to the bit line BL, and a second terminal of the cell transistor Tr may be connected to the ferroelectric capacitor FC.

A first electrode of the ferroelectric capacitor FC may be connected to the cell transistor Tr, and a second electrode of the ferroelectric capacitor FC may be connected to the plate line PL. When the cell transistor Tr is turned on by activating the word line WL, the first electrode of the ferroelectric capacitor FC may be electrically connected to the bit line BL, and the second electrode of the ferroelectric capacitor FC may be electrically connected to the plate line PL.

The ferroelectric capacitors FC may include ferroelectric materials and may have the characteristics of spontaneous electric polarization. Therefore, the ferroelectric capacitor FC can maintain remanent polarization in the absence of an external electric field. The ferroelectric materials may include barium titanate (BaTiO3), lead, titanate (PbTiO3), lead zirconium titanate (PZT), and strontium bismuth tantalate (SBT), or the like, but is not limited thereto.

When the cell transistor Tr is turned on by activating the word line WL, a cell voltage Vc, which is a difference between the voltage provided from the bit line BL and the voltage provided from the plate line PL, may be applied across the ferroelectric capacitor FC.

By changing the polarization state for the ferroelectric capacitor FC based on the cell voltage Vc, the write or read operation on the ferroelectric memory cell MC may be performed. In order to perform the write or read operation with respect to the ferroelectric memory cell MC, the bias voltage may be provided through the bit line BL and the plate line PL in various manners. For example, by applying a positive voltage to the bit line BL and applying a ground voltage to the plate line PL, the cell voltage Vc of a positive voltage may be applied to the ferroelectric capacitor FC. In addition, by applying the ground voltage to the bit line BL and applying a positive voltage to the plate line PL, the cell voltage Vc of a negative voltage may be applied to the ferroelectric capacitor FC.

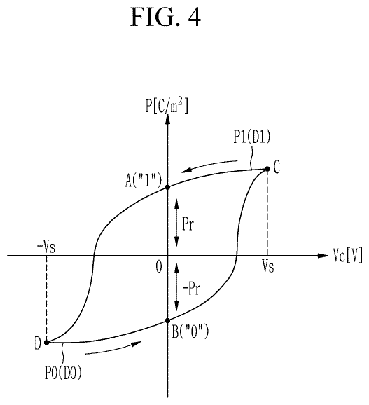

FIG. 4 is a hysteresis curve for explaining an operation of the ferroelectric memory cell according to an embodiment. Specifically, FIG. 4 explains a polarization state of the ferroelectric capacitor FC corresponding to the cell voltage Vc applied to the ferroelectric capacitor FC.

Referring to FIG. 3 and FIG. 4, the ferroelectric capacitor FC may have a hysteresis characteristic, in which polarization state may be changed differently depending on a polarization directions D0 and D1. The cell voltage Vc may be referred to as a voltage difference applied across the ferroelectric memory cell, in which the cell voltage corresponds to the voltage difference between the bit line voltage and the plate line voltage.

When the cell voltage Vc applied across the ferroelectric capacitor FC is 0V and external electric field is not established in the ferroelectric capacitor FC, the polarization state of the ferroelectric capacitor FC may be in one of a first remanent polarization state A or a second remanent polarization state B. Although a second polarization direction D0 is described as a positive polarization and a first polarization direction D1 is described as a negative polarization, they may be represented differently depending on embodiments.

If the ferroelectric capacitor FC is aligned in the first polarization direction D1 when the cell voltage Vc is 0V, the polarization state of the ferroelectric capacitor FC may be in the first remanent polarization state A, and the ferroelectric capacitor FC may be polarized to the extent of a positive remanent polarization Pr. When the ferroelectric capacitor FC is aligned in the first polarization direction D1, the polarization state of the ferroelectric capacitor FC may change along a first path P1 as shown in FIG. 4.

By applying different voltages to the plate line PL and the bit line BL for changing the cell voltage Vc, a negative saturation polarization voltage −Vs may be applied across the ferroelectric capacitor FC. The polarization state of the ferroelectric capacitor FC may be changed to the second saturation polarization state D along the first path P1, and the polarization direction of the ferroelectric capacitor FC may be changed from the first polarization direction D1 to the second polarization direction D0. The negative saturation polarization voltage −Vs may be −2.0V to −0.8, preferably −1.1V to −0.9V.

By applying different voltages to the plate line PL for changing the cell voltage Vc, a positive saturation polarization voltage Vs may be applied across the ferroelectric capacitor FC. The polarization state of the ferroelectric capacitor FC may be changed to the first saturation polarization state C along the first path P0, and the polarization direction of the ferroelectric capacitor FC may be changed from the second polarization direction D0 to the first polarization direction D1. The positive saturation polarization voltage Vs may be 0.8V to 2.0V, and preferably 0.9V to 1.1V.

If the ferroelectric capacitor FC is aligned in the second polarization direction D0 when the cell voltage Vc is 0V, the polarization state of the ferroelectric capacitor FC may be the second remanent polarization state B, and the ferroelectric capacitor FC may be polarized to the extent of a negative remanent polarization-Pr. When the ferroelectric capacitor FC is aligned in the second polarization direction D0, the polarization state of the ferroelectric capacitor FC may change along a first path P0 as shown in FIG. 4.

By applying different voltages to the plate line PL and the bit line BL for changing the cell voltage Vc, a positive saturation polarization voltage Vs is applied across the ferroelectric capacitor FC, the polarization state of the ferroelectric capacitor FC may be changed to first saturation polarization state C along the path P0, and the polarization direction of the ferroelectric capacitor FC may be changed from the second polarization direction D0 to the first polarization direction D1. The positive saturation polarization voltage Vs may be referred to as “saturation polarization voltage,” and the saturation polarization voltage Vs may be 0.8V to 2.0V, and preferably 0.9V to 1.1V.

By applying different voltages to the plate line PL for changing the cell voltage Vc, a negative saturation polarization voltage −Vs is applied across the ferroelectric capacitor FC, the polarization state of the ferroelectric capacitor FC may be changed to second saturation polarization state D, and the polarization direction of the ferroelectric capacitor FC may be changed from the first polarization direction D1 to the second polarization direction D0. The negative saturation polarization voltage −Vs may be −2.0V to −0.8, preferably −1.1V to −0.9V.

According to remanent polarization states A and B of the ferroelectric capacitor FC, the ferroelectric memory cell MC may retain corresponding data. For example, when the cell voltage Vc applied across the ferroelectric capacitor FC is 0V, and the polarization state of the ferroelectric capacitor FC is the first remanent polarization state A, the ferroelectric memory cell MC may store the logic high “1.” When the cell voltage Vc applied across the ferroelectric capacitor FC is 0V, and the polarization state of the ferroelectric capacitor FC is the second remanent polarization state B, the ferroelectric memory cell MC may store the logic low “0.”

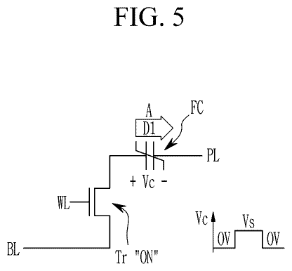

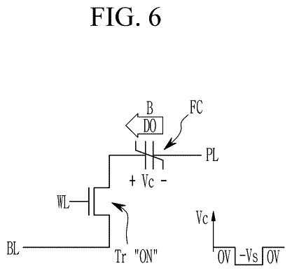

FIG. 5 to FIG. 6 are drawings for explaining a write operation of the ferroelectric memory cell according to an embodiment.

Referring to FIG. 3 to FIG. 6, for the ferroelectric memory cell MC to store the logic high “1,” the cell transistor Tr may be turned on by applying activating voltage to the word line WL, and the positive saturation polarization voltage Vs may be applied across the ferroelectric capacitor FC as the cell voltage Vc.

When the cell transistor Tr is turned on, and the positive saturation polarization voltage Vs is applied across the ferroelectric capacitor FC, the polarization state of the ferroelectric capacitor FC may be changed to first saturation polarization state C, and the polarization direction of the ferroelectric capacitor FC may be the first polarization direction D1.

When the ferroelectric memory cell MC enters into a standby mode, in which the word line is deactivated and the cell voltage Vc applied across the ferroelectric capacitor FC is changed to 0V, the polarization state of the ferroelectric capacitor FC may be changed to the first remanent polarization state A, and the polarization direction of the ferroelectric capacitor FC may be maintained in the first polarization direction D1. Accordingly, the ferroelectric memory cell MC may store the logic high “1.”.

For the ferroelectric memory cell MC to store the logic low “0,”, the cell transistor Tr may be turned on by applying activating voltage to the word line WL, and the negative saturation polarization voltage −Vs may be applied across the ferroelectric capacitor FC as the cell voltage Vc. When the cell transistor Tr is turned on, and the negative saturation polarization voltage −Vs is applied to the ferroelectric capacitor FC, the polarization state of the ferroelectric capacitor FC may be changed to the second saturation polarization state D along the path P1, and the polarization direction of the ferroelectric capacitor FC may be changed to the second polarization direction D0.

When the ferroelectric memory cell MC enters into the standby mode, in which the word line is deactivated and the cell voltage Vc applied across the ferroelectric capacitor FC is changed to 0V, the polarization state of the ferroelectric capacitor FC may be changed to the second remanent polarization state B along the path P0, and the polarization direction of the ferroelectric capacitor FC may retain the second polarization direction D0. Accordingly, the ferroelectric memory cell MC may store the logic low “0.”.

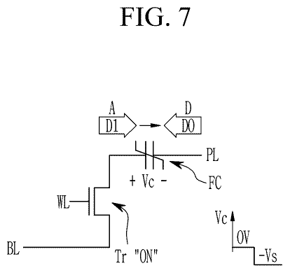

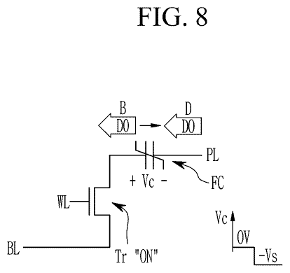

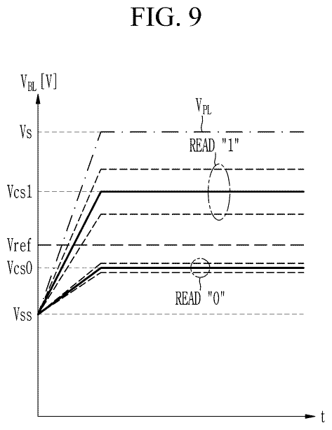

FIG. 7 to FIG. 8 are drawings for illustrating a read operation of the ferroelectric memory cell according to an embodiment. FIG. 9 is a voltage graph for illustrating a charge sharing period within the read operation of the ferroelectric memory cell according to an embodiment.

Referring to FIG. 3, FIG. 4, and FIG. 7 to FIG. 9, regardless of the data stored in the ferroelectric memory cell MC, the cell transistor Tr may be turned by applying word line activation voltage to the word line, and by applying the plate line voltage to the plate line and apply ground voltage to the bit line, the negative saturation polarization voltage −Vs as the cell voltage Vc may be applied across the ferroelectric capacitor FC.

The negative saturation polarization voltage −Vs may be applied to across the ferroelectric capacitor FC by applying the plate line voltage the plate line PL, in which the plate line voltage may be set close to the positive saturation polarization voltage Vs of the ferroelectric capacitor FC, and a ground voltage Vss may be applied to the bit line BL, in which the ground voltage Vss may be 0V, but is not limited thereto.

In a standby mode, if the ferroelectric memory cell MC stores data of the logic high “1,” the polarization state of the ferroelectric capacitor FC may be the first remanent polarization state A and no external electric field is established across the ferroelectric capacitor FC. The ferroelectric memory device may enter into an activation mode by applying the word line driving voltage to the word line and the plate line voltage to the plate line, the negative saturation polarization voltage −Vs may be across the ferroelectric capacitor FC as the cell voltage Vc in the first remanent polarization state A, the polarization state of the ferroelectric capacitor FC may be changed to the second saturation polarization state D along the path P1, and the polarization direction of the ferroelectric capacitor FC may be reversed from the first polarization direction D1 to the second polarization direction D0.

According to the change of the polarization state, the charges stored in the ferroelectric capacitor FC in the charge sharing period may be shared with the bit line, thereby a voltage of the bit line BL may be changed to a first charge sharing voltage Vcs1 as in the following Equation 1. Because the ferroelectric memory cell MC stores the logic high “1,” the first charge sharing voltage Vcs1 may have a potential higher than a predetermined reference voltage Vref.

$$V cs 1 = \frac{CFC}{CFC + CBL} \times V PL + \frac{2 Pr \times {A}_{FE}}{CFC + CBL} \qquad Equation 1$$

Referring to Equation 1, Vcs1 is the first charge sharing voltage Vcs1, and CFC is a capacitance of the ferroelectric capacitor FC, CBL is a capacitance between the bit line BL and the ground, VPL is a plate line voltage applied to the plate line PL, Pr is the remanent polarization Pr, and A_{FE} is a cross-section area of the ferroelectric capacitor FC.

In the standby mode, If the ferroelectric memory cell MC stores data of the logical low “0”, the polarization state of the ferroelectric capacitor FC may be the second remanent polarization state B when no external electric field is established across the ferroelectric capacitor FC. The ferroelectric memory device may enter into the activation mode by applying the word line driving voltage to the word line and the plate line voltage to the plate line. When the negative saturation polarization voltage −Vs is applied across the ferroelectric capacitor FC as the cell voltage Vc in the second remanent polarization state B, the polarization state of the ferroelectric capacitor FC be changed to second saturation polarization state D, and the polarization direction of the ferroelectric capacitor FC may maintain the second polarization direction D0 without reversal.

According to the polarization state change, the charges stored in the ferroelectric capacitor FC in the charge sharing period may be shared with the bit line BL, and the voltage of the bit line BL may be changed to a second charge sharing voltage Vcs0 as shown in Equation 2. Because the ferroelectric memory cell MC stores data of the logic low “0,” the second charge sharing voltage Vcs0 may have a potential lower than the predetermined reference voltage Vref.

$$V cs = \frac{CFC}{CFC + CBL} \times V PL \qquad Equation 2$$

Referring to Equation 2, Vcs0 is the second charge sharing voltage Vcs0, and CFC is the capacitance of the ferroelectric capacitor FC, CBL is the capacitance between the bit line BL and the ground, and VPL is the plate line voltage applied to the plate line PL.

The ferroelectric memory device 200a may detect a charge sharing voltage of the bit line BL based on the reference voltage Vref, thereby sense the stored data of the ferroelectric memory cell MC.

According to an embodiment, regardless of the data stored in the ferroelectric memory cell MC, the polarization direction of the ferroelectric capacitor FC is changed into or remains as one polarization direction after the charge sharing period. Because the ferroelectric memory device 200a has the destructive readout characteristic that does not preserve the stored data, the ferroelectric memory device 200a needs to perform the rewrite operation for restoring the stored data while performing the sensing operation and the read operation on the ferroelectric memory cell MC.

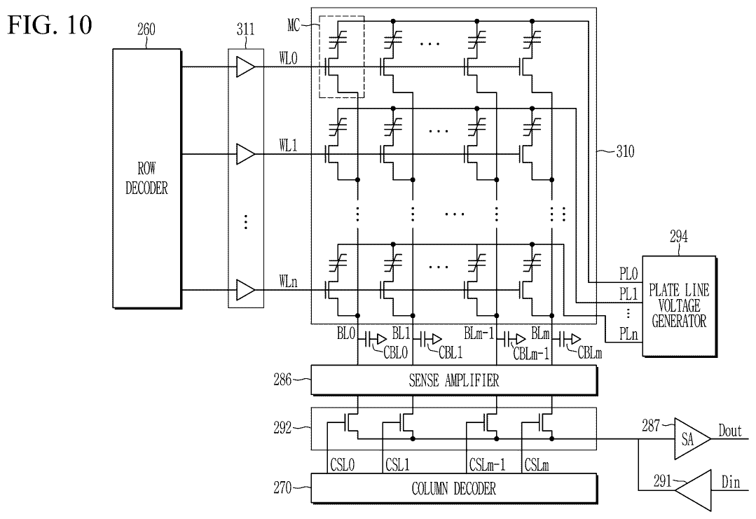

FIG. 10 is a drawing for illustrating the bank array according to an embodiment. More particularly, the bank array 310 of FIG. 10 may be one of the first to fourth bank arrays 310 to 340.

Referring to FIG. 2, FIG. 3, and FIG. 10, the bank array 310 may include the plurality of word lines WL0 to WLn, the plurality of bit lines BL0 to BLm, the plurality of plate lines PL0 to PLn, and the plurality of ferroelectric memory cells MC disposed in regions where the word lines WL0 to WLn and the bit lines BL0 to BLm intersect each other, where each of m and n is a natural number of 2 or greater.

Each of the ferroelectric memory cells MC may include the cell transistor Tr and the ferroelectric capacitor FC.

The first terminal of the cell transistor Tr may be connected to the first electrode of the ferroelectric capacitor FC, and the second terminal of the cell transistor Tr may be connected to a first bit line BL0. A gate terminal of a cell transistor TR may be connected to a first word line WL0. The first terminal may be a drain terminal, and second terminal may be a source terminal, but is not limited thereto. The second electrode of the ferroelectric capacitor FC may be connected to a first plate line PL0.

The plurality of word lines WL0 to WLn may be connected to a word line driver 311, and the plurality of word lines WL0 to WLn may be activated by the row decoder 260 through the word line driver 311.

The row decoder 260 of FIG. 10 may be one of the first to fourth bank row decoders 260a to 260d of FIG. 2.

The row decoder 260 may activate the word line corresponding to the row address ROW_ADDR among the plurality of word lines WL0 to WLn in response to a row activation command. The word line driver 311 may provide the word line driving voltage to the word line to be activated. The word line driving voltage may be a high-voltage Vpp which may be a boosted voltage higher than a power supply voltage. The word line driving voltage may be applied to the word line for performing read or write operations, in which read data and write data are sensed from or written into the ferroelectric memory cell MC. The cell transistor Tr of the ferroelectric memory cell MC connected to the activated word line may be turned on to connect the bit line with the ferroelectric capacitor FC.

A plate line voltage generator 294 may generate the plate line voltage and may provide the plurality of plate lines PL0 to PLn with the plate line voltage. The plate line voltage generator 294 may receive the address signal ADDR while receiving the row activation command, may select the plate line among the plurality of plate lines PL0 to PLn to provide the plate line driving voltage to the selected plate line corresponding to the address signal. The selected plate line may correspond to the activated word line. For example, when the first word line WL0 is activated, the corresponding first plate line PL0 may be selected, and the plate line driving voltage is applied to the first plate line PL0.

In addition, the plate line voltage generator 294 may provide the ground voltage to a non-selected plate line. The address signal ADDR may be the row address, but is not limited thereto.

Upon receiving a precharge command, the plate line voltage generator 294 of the FeRAM may provide the ground voltage to the plurality of plate lines PL0 to PLn as a precharge voltage.

Each of the plurality of bit lines BL0 to BLm may be connected to a plurality of bit lines, in which each of the plurality of bit lines BL0 to BLm has parasitic capacitances CBL0 to CBLm between the ground and the plurality of bit lines BL0 to BLm. During the sensing period, the cell transistor Tr is turned on and the charge stored in the ferroelectric capacitor FC are shared with the plurality of bit lines which have capacitances CBL0 to CBLm. Accordingly, the bit line voltage may be changed to a charge sharing voltage which may be different values depending on the data stored in the ferroelectric memory cell MC.

A first sense amplifier 286 may sense and amplify the voltage of the bit line changed in response to the row activation command. The first sense amplifier 286 may include a latch to store the amplified voltage of the bit line. The first sense amplifier 286 may detect the charge sharing voltage of the bit line in response to the row activation command, and may pull up or pull down the voltage of the bit line to an amplified voltage or the ground voltage based on a predetermined reference voltage.

Upon detecting a bit line voltage greater than the predetermined reference voltage in the sensing operation, the first sense amplifier 286 may pull up the voltage of the bit line to the amplified voltage. Likewise, upon detecting a bit line voltage smaller than the predetermined reference voltage in the sensing operation, the first sense amplifier 286 may pull down the voltage of the bit line to the ground voltage. The amplified voltage may be greater than the plate line driving voltage. For example, the potential of the amplified voltage may be 2 times to 2.5 times higher than the potential of the plate line driving voltage. The first sense amplifiers 286 may be one of the first to fourth bank sense amplifiers 285a to 285d of FIG. 2.

Upon receiving a precharge command, the first sense amplifier 286 may provide the ground voltage to the plurality of bit lines BL0 to BLm as a precharge voltage. The first sense amplifier 286 may be referred to as a bit line sense amplifier or a local sense amplifier.

The plurality of bit lines BL0 to BLm may be connected to data lines through a column selection transistors controlled by a plurality of column selection lines CSL0 to CSLm, in which the column selection lines CSL0 to CSLm may be selected by the column decoder 270. The column decoder 270 may receive an address signal with respect to the read/write command, and may select the column selection lines CSL0 to CSLm corresponding to the address signal. The address signal may be the column address, but is not limited thereto. The selected column selection line may turn on corresponding column selection transistors in the column selection circuit 292, and the corresponding bit lines BL0 to BLm may be selected.

The column decoder 270 of FIG. 10 may be one of the first to fourth bank column decoders 270a to 270d of FIG. 2.

A second sense amplifier 287 may read the sensed data from the bit lines selected in response to the read command. The second sense amplifier 287 may amplify the sensed data from the selected bit lines, and may provide output data Dout through data I/O buffer 295. The second sense amplifier 287 may be referred to as a global sense amplifier.

A write driver 291 may drive a voltage, which is one of the ground voltage and a write voltage depending on the input data Din, to the bit line selected in response to the write command. The write voltage and the amplified voltage may have voltages of the same potential.

During the write operation in response to the write command, when the data sensed by the first sense amplifier 286 and the input data Din for the write command provided from the memory controller 100 are different from each other, the write driver 291 may drive the voltage of the selected bit line to the write voltage or the ground voltage depending on the input data Din.

For example, the write driver 291 may provide the ground voltage to the selected bit line when the input data Din is the logic low “0.” The write driver 291 may provide the write voltage to the selected bit line when the input data Din is the logic high “1.”

When the voltage to be driven by the write driver is identical with the selected bit line voltage after the sensing operation, the write driver 291 may drive the selected bit line to the same potential of the selected bit line.

Alternatively, when the write driver 291 performs the write operation, the first sense amplifier 286 may be inactivated, and the write driver 291 may drive the selected bit line to the same potential of the selected bit line.

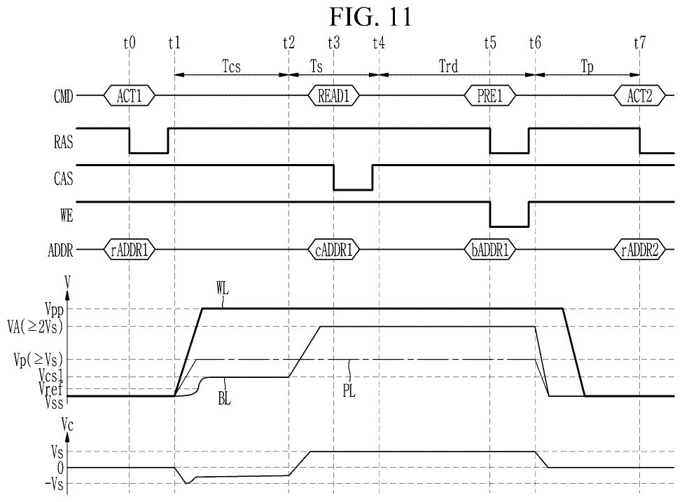

FIG. 11 is a timing diagram for illustrating the read operation of the ferroelectric memory cell MC. More particularly, FIG. 11 illustrates a read operation sequence of the ferroelectric memory device 200a when the stored data in the ferroelectric memory cell MC is the logic high “1.”

Referring to FIG. 2, FIG. 4, FIG. 10 and FIG. 11, when the ferroelectric memory device 200a is in a precharged state before a time point to, the plate line PL and the bit line BL may be precharged to the ground voltage Vss.

At the time point to, the ferroelectric memory device 200a may receive a first row activation command ACT1 together with a first row address rADDR1 that is the row address ROW_ADDR. The row activation command may precede the read command, the write command, and the precharge command. The write or read command may be received after a first time delay from receiving the row activation command, in which the first time delay is required for activating a word line selected by the first row activation command ACT1 and the first row address rADDR1. A precharge command may be received after a second time delay from receiving the write or read command, in which the second time delay is required for completing the read or write operation based on the write or read command.

The first row activation command ACT1 may be received by transitioning the row address strobe signal RAS to logic low, and the first row address rADDR1 received together may become a valid address for the activation operation. The first row address rADDR1 may include row information with respect to the word line WL to be activated.

At a time point t1, the row decoder 260 may activate the word line WL corresponding to the first row address rADDR1, and the word line driver 311 may provide a word line driving voltage Vpp to the activated word line WL. The word line driving voltage Vpp may be 1.5 times to 2 times higher than the supply voltage. For example the word line driving voltage Vpp may be 3V to 5V when the power supply voltage is 1.5V to 2.5V. In addition, the plate line voltage generator 294 may select the plate line PL corresponding to the first row address rADDR1, and provide a plate line voltage Vp to the selected plate line PL. The plate line voltage Vp may be greater than or equal to the saturation polarization voltage Vs of the ferroelectric memory cell MC, thereby the potential of the plate line voltage Vp may be equal to the potential of the saturation polarization voltage Vs.

By applying the plate line voltage Vp and the word line driving voltage Vpp to the selected word line WL and the selected plate line PL respectively, the cell voltage Vc applied across the ferroelectric capacitor FC may be changed to the negative saturation polarization voltage −Vs from 0V of the precharged state, and the polarization state of the ferroelectric capacitor FC may be changed depending on the data stored in the ferroelectric memory cell MC.

As the polarization state changes, charges of the ferroelectric capacitor FC may be shared with the bit line BL connected to the ferroelectric memory cell MC selected by the row activation command. During the charge sharing operation, the voltage of the bit line BL connected to the ferroelectric memory cell MC storing the data of the logic high “1” may be changed from the ground voltage to the first charge sharing voltage Vcs1.

At a time point t2, the first sense amplifier 286 may detect the first charge sharing voltage Vcs1 of the bit line BL, and may compare the first charge sharing voltage Vcs1 with the reference voltage Vref, and may amplify the voltage difference between the first charge sharing voltage Vcs1 and the reference voltage Vref. Because the reference voltage Vref is preset to be lower than the first charge sharing voltage Vcs1, the voltage of the selected bit line may be pulled up to reach an amplified voltage VA.

The amplified voltage VA may be 2 times to 2.5 times higher than the plate line voltage Vp. For example, the amplified voltage VA may be 2V to 4V, and preferably 2V to 2.5V, when the plate line driving voltage Vp is 1V. The plate line voltage Vp may have the same potential as the saturation polarization voltage Vs.

During the sensing operation for the row activation command, the cell voltage Vc applied across the ferroelectric memory cell MC due to the amplified voltage VA for the bit line BL of the first sense amplifier 286 may reach the saturation polarization voltage Vs, and the polarization state and the polarization direction of the ferroelectric capacitor FC may be changed from the polarization direction D0 to the polarization direction D1.

According to the change of the polarization direction, the ferroelectric memory cell MC connected to the bit line BL stored data of the logic high “1” before charge sharing may be re-written to restore data of the logic high “1,” and the ferroelectric capacitor FC may recover the data which are lost during the charge sharing operation.

The ferroelectric memory device 200a may perform the rewrite operation with respect to the logic high “1” along with the sensing operation with respect to the logic high “1,” through amplifying the charge sharing voltage to the amplified voltage VA which is higher than the plate line voltage Vp.

At a time point t3, the ferroelectric memory device 200a may receive a first read command READ1 together with a first column address cADDR1 that is the column address COL_ADDR.

The first read command READ1 may be received by transitioning the column address strobe signal CAS to logic low, and the first column address cADDR1 received together may become a valid address for the read operation. The first column address cADDR1 may include the column address information with respect to the bit line BL, and the read operation is performed based on the column address information.

At a time point t4, the column decoder 270 may turn on the column selection transistor by applying a selection voltage to the column selection line corresponding to the first column address cADDR1, and the bit line BL and the data line DL coupled to the column switch are electrically connected to each other.

The second sense amplifier 287, which is connect to the data line DL, may read data sensed from the bit line corresponding to the first column address cADDR1. The second sense amplifier 287 may amplify the data sensed from the selected bit line, and may output the output data Dout of the logic high “1”.

At a time point t5, the ferroelectric memory device 200a may receive a first precharge command PRE1 together with a first bank address bADDR1 that is the bank address BANK_ADDR.

Upon receiving the first precharge command PRE1, the row address strobe signal RAS and the write enable signal WE may transition to logic low, and the first bank address bADDR1 received together may become a valid address for the precharge operation. The first bank address bADDR1 may include address information of a bank in which the precharge operation is performed.

At a time point t6, the first sense amplifier 286 may provide the ground voltage Vss to the bit line BL in the selected bank, and the plate line voltage generator 294 may provide the ground voltage Vss to the plate line PL in the selected bank. The word line driver 311 may apply turn off voltage to the activated word line WL, and deactivate the word line WL by pulling down its voltage to the ground voltage Vss. Each of the first sense amplifier 286 and the plate line voltage generator 294 may provide the ground voltage Vss to each of the bit line BL and the plate line PL respectively in the selected bank.

The precharge operation may be completed in a precharge period, in which the voltages of the word line WL, the bit line BL, and the plate line PL are pulled down to the ground voltage Vss. At the time point t6, the ferroelectric memory device 200a may receive a second row activation command ACT2 together with a second row address rADDR2.

During the charge sharing period Tcs between the time point t1 and the time point t2, the data stored in the ferroelectric memory cell MC may be lost due to the charge sharing operation and the polarization direction of the ferroelectric capacitor FC may be reversed. Therefore, the stored data in the ferroelectric memory cell MC needs to be re-written in the ferroelectric memory cell MC.

During a sensing period Ts between the time point t2 and the time point t4, the amplification operation by the first sense amplifier 286 may be performed, in which the voltage of the bit line BL may be pulled up to the amplified voltage VA based on the stored data in the ferroelectric memory cell MC which is the logic high “1.” Because the bit line voltage is pulled up to the amplified voltage VA, the cell voltage Vc applied across the ferroelectric capacitor FC may reach the saturation polarization voltage Vs. The sensing operation and the rewrite operation, in which the polarization direction of the ferroelectric capacitor FC is changed, may be performed simultaneously.

The read operation of the logic high “1” is performed during the time period between t4 and t6. The precharge command PRE1 may be received after a third delay from the receiving of the read command READ1. The third delay is required to complete the read operation requested by the read command READ1. Upon receiving the precharge command PRE1, during a precharge period Tp between the time point t6 and a time point t7, the bit line BL and the plate line PL may be pulled down to the ground voltage.

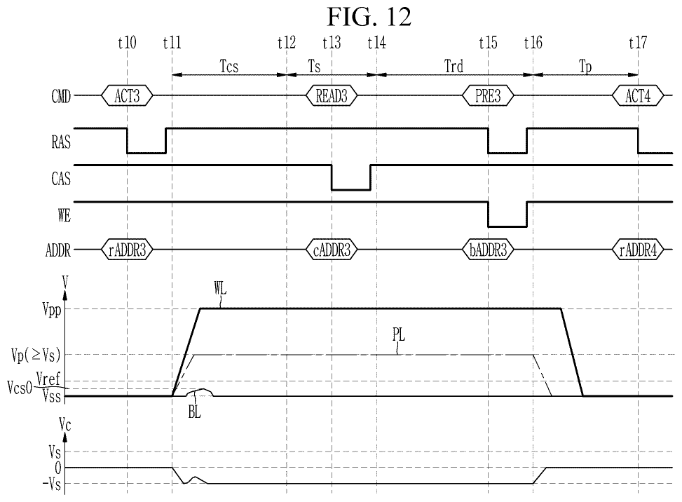

FIG. 12 is a timing diagram for illustrating the read operation of the ferroelectric memory cell. More particularly, FIG. 12 illustrates a read operation sequence of the ferroelectric memory device 200a, when the stored data in the ferroelectric memory cell is the logic low “0.”

Referring to FIG. 2, FIG. 4, FIG. 10 and FIG. 12, when the ferroelectric memory device 200a is in a precharged state before a time point t10, the plate line PL and the bit line BL may be precharged to the ground voltage Vss.

At the time point t10, the ferroelectric memory device 200a may receive a third row activation command ACT3 together with a third row address rADDR3.

The third activation command ACT3 may be received by transitioning the row address strobe signal RAS to logic low, and the third row address rADDR3 received together may become a valid address for the activation operation. The third row address rADDR3 may include row information with respect to the word line WL to be activated.

At a time point t11, the row decoder 260 may activate the word line WL corresponding to the third row address rADDR3, and the word line driver 311 may provide the word line driving voltage Vpp to the activated word line WL. In addition, the plate line voltage generator 294 may select the plate line PL corresponding to the third row address rADDR3, and provide the plate line voltage Vp to the selected plate line PL.

By applying the plate line voltage Vp and the word line driving voltage Vpp to the selected word line WL and the selected plate line PL respectively, the cell voltage Vc applied across the ferroelectric capacitor FC may reach the negative saturation polarization voltage −Vs, and the polarization state of the ferroelectric capacitor FC may be changed.

As the polarization state changes, charges of the ferroelectric capacitor FC may be shared with the bit line BL of the ferroelectric memory cell MC selected by the selected word line WL and the selected plate line PL. During the charge sharing operation, the voltage of the bit line BL connected to the ferroelectric memory cell MC storing the data of the logic low “0” may be changed from the ground voltage to the second charge sharing voltage Vcs0.

At a time point t12, the first sense amplifier 286 may detect the second charge sharing voltage Vcs0 of the bit line BL, and may compare the second charge sharing voltage Vcs0 with the reference voltage Vref, and may amplify the voltage difference between the first charge sharing voltage Vcs0 and the reference voltage Vref. Because the reference voltage Vref is preset to be higher than the second charge sharing voltage Vcs0, the voltage of the selected bit line may be pulled down to the ground voltage Vss.

During the sensing operation for the row activation command ACT3, the cell voltage Vc applied across the ferroelectric memory cell MC due to the ground voltage Vss for the bit line BL of the first sense amplifier 286 may reach the negative saturation polarization voltage −Vs, and the polarization state of the ferroelectric capacitor FC may be changed but the polarization direction may remain as polarization direction D0.

Because the polarization direction is maintained, the ferroelectric memory cell MC connected to the bit line BL and the plate line PL may preserve the data of the logic low “0.”

The ferroelectric memory device 200a may perform the rewrite operation with respect to the logic low “0” along with the sensing operation with respect to the logic low “0,” through amplifying the charge sharing voltage Vcs0 to the ground voltage which is lower than the plate line driving voltage

At a time point t13, the ferroelectric memory device 200a may receive a third read command READ3 together with a third column address cADDR3.

The third read command READ3 may be received by transitioning the column address strobe signal CAS to logic low, and the third column address cADDR3 received together may become a valid address for the read operation. The third column address cADDR3 may include the column address information with respect to the bit line BL, with which the read operation is performed.

At a time point t14, in response to the third read command READ3, the column decoder 270 may turn on the column switch transistor by applying a selection voltage on the column selection line corresponding to the third column address CADDR3, and the bit line BL and the data line DL coupled to the column switch are electrically connected to each other.

The second sense amplifier 287, which is connect to the data DL, may read the data sensed from the bit line corresponding to the third column address cADDR3. The second sense amplifier 287 may amplify the data sensed from the selected bit line, and may output the output data Dout, which is the logic low “0.”

At a time point t15, the ferroelectric memory device 200a may receive a third precharge command PRE3 together with a third bank address bADDR3.

Upon receiving the third precharge command PRE3, the row address strobe signal RAS and the write enable signal WE may transition to logic low, and the third bank address bADDR3 received together may become a valid address for the precharge operation. The third bank address bADDR3 may include address information of a bank in which the precharge operation is performed.

At a time point t16, the first sense amplifier 286 may drive the bit line BL to the ground voltage in the selected bank, and the plate line voltage generator 294 may provide the ground voltage Vss to the plate line PL in the selected bank. The word line driver 311 may apply turn off voltage to the activated word line WL, and deactivate the word line WL by pulling down its voltage to the ground voltage Vss. Each of the first sense amplifier 286 and the plate line voltage generator 294 may provide the ground voltage Vss to each of the bit line BL and the plate line PL respectively in the selected bank.

The precharge operation may be completed in a precharge period, in which the voltages of word line WL, the bit line BL, and the plate line PL are pulled down to the ground voltage Vss. At the time point t16, the ferroelectric memory device 200a may receive a fourth activation command ACT4 together with a fourth row address rADDR4.

During the charge sharing period Tcs, the polarization state of the ferroelectric capacitor FC may be changed but the polarization direction may be maintained such that the data stored in the ferroelectric memory cell MC may be maintained. Therefore, the stored data in the ferroelectric memory cell MC needs not to be re-written

During the sensing period Ts between the time point t12 and the time point t14, the amplification operation by the first sense amplifier 286 may be performed, in which the voltage of the bit line BL may be pulled down to the ground voltage Vss based on the stored data in the ferroelectric memory cell MC which is the logic low “0.” Because the bit line voltage is pulled down to the ground voltage Vss, the cell voltage Vc applied across the ferroelectric capacitor FC may reach the negative saturation polarization voltage −Vs. Because the polarization direction of the ferroelectric capacitor FC may be maintained during the sensing period Ts, the data stored in the ferroelectric memory cell MC may be preserved.

The read operation for the data of the logic low “0” is performed during the time period between t4 and t16. The precharge command PRE3 may be received after a third delay from the receiving of the read command READ3. The third delay is required to complete the read operation requested by the read command READ3. Upon receiving the precharge command PRE3, during the precharge period Tp between the time point t16 and a time point t17, the bit line BL and the plate line PL may be pulled down to the ground voltage.

Because the cell voltage of the ferroelectric memory cell MC is changed depending on the stored data in the ferroelectric memory cell, the rewrite operation may be performed in a branched manner depending on the stored data value. Some of the branched rewrite operations may be performed in a delayed write back manner during the precharge period, in which the access time of the memory device may be increased and deteriorate the performance of the ferroelectric memory device. Providing a fixed voltage the plate line regardless of whether the ferroelectric memory cell is accessed or not. The application of the fixed voltage to the plate line may cause an inefficient power consumption and degraded operation speed of the ferroelectric memory device.

According to an embodiment, a ferroelectric memory device may perform the rewrite operation before the precharge period without a branch regardless of the stored data. Instead of providing fixed voltage to the plate line, by applying different voltages to the plate line between in the precharged state and in the activated state, power consumption and operation speed of the ferroelectric memory device may be improved.

Referring to FIG. 11 and FIG. 12, during the sensing period Ts and the read period Trd, the ferroelectric memory cell MC may be in a state of saturation polarization voltage Vs or the negative saturation polarization voltage −Vs depending on the sensed data. By applying different voltages to the plate line PL depending on whether it is in the precharged state or in the activated state, the ferroelectric memory device 200a may perform the rewrite operation in the sensing period Ts and the reading period Trd, regardless of the stored data.

The ferroelectric memory device 200a may not only improve the power consumption, but also improve the access time by performing the rewrite operation together in the sensing period Ts and the reading period Trd. The ferroelectric memory device 200a may reduce the precharge period Tp and reduce row activation time by completing the rewrite operation before the precharge period Tp without branching and performing a part of the rewrite operation in a delayed write back manner in the precharge period Tp.

FIG. 11 shows an operation sequence of the ferroelectric memory device 200a performed to read the data of the logic high “1” stored in the ferroelectric memory cell, and FIG. 12 shows an operation sequence of the ferroelectric memory device 200a performed to read the data of the logic low “0” stored in the ferroelectric memory cell.

The operation sequence of the ferroelectric memory device 200a in FIG. 11 and FIG. 12 may be equally applied regardless of whether the stored the data is the logic high “1” or the logic low “0.” When the sensed data from the ferroelectric memory cell is the same as the data to be written into the ferroelectric memory cell, the ferroelectric memory device 200a may perform the sensing operation and the rewrite operation together in the sensing period Ts, thereby reducing the precharge time and reducing the memory access time.

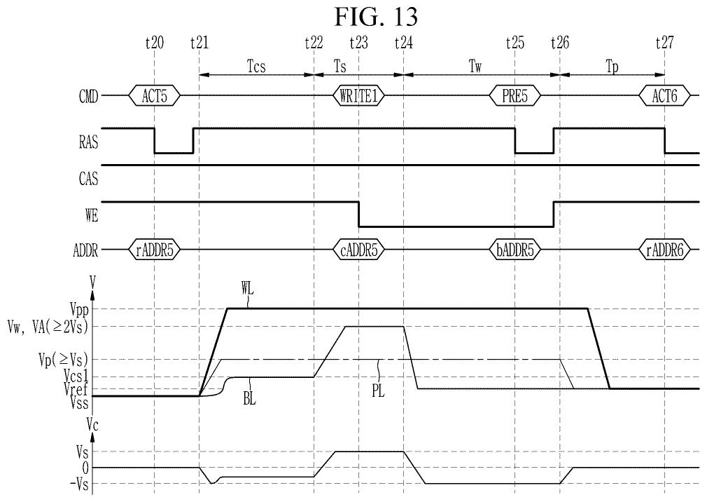

FIG. 13 is a timing diagram for illustrating the write operation of the ferroelectric memory cell. More particularly, FIG. 13 illustrates a write operation sequence of the ferroelectric memory device 200a performed to write the data of the logic low “0” to the ferroelectric memory cell storing the data of the logic high “1”.

Referring to FIG. 2, FIG. 4, FIG. 10 and FIG. 13, in the precharged state before a time point t20, the plate line PL and the bit line BL may be precharged to the ground voltage Vss.

At the time point t20, the ferroelectric memory device 200a may receive a fifth activation command ACT5 together with a fifth row address rADDR5.

The fifth activation command ACT5 may be received by transitioning the row address strobe signal RAS to logic low, and the fifth row address rADDR5 received together may become a valid address for the activation operation. The fifth row address rADDR5 may include row information with respect to the word line WL to be selected.

At a time point t21, the row decoder 260 may activate the word line WL corresponding to the fifth row address rADDR5, and the word line driver 311 may provide the word line driving voltage Vpp to the activated word line WL. In addition, the plate line voltage generator 294 may select the plate line PL corresponding to the fifth row address rADDR5, and provide the plate line voltage Vp to the selected plate line PL.

By applying the plate line voltage Vp and the word line driving voltage Vpp to the selected word line WL and the selected plate line PL respectively, the cell voltage Vc applied across the ferroelectric capacitor FC may reach the negative saturation polarization voltage −Vs, and polarization state and the polarization direction of the ferroelectric capacitor FC may be changed.

As the polarization state changes, charges of the ferroelectric capacitor FC may be shared with the bit line BL of the ferroelectric memory cell MC selected by the selected word line WL and the selected plate line PL. During the charge sharing, the voltage of the bit line BL connected to the ferroelectric memory cell MC may be changed from the ground voltage to the first charge sharing voltage Vcs1.

At a time point t22, the first sense amplifier 286 may detect the first charge sharing voltage Vcs1 of the bit line BL, and may compare the first charge sharing voltage Vcs1 with the reference voltage Vref, and may amplify the voltage difference between the first charge sharing voltage Vcs1 and the reference voltage Vref. Because the reference voltage Vref is preset to be lower than the first charge sharing voltage Vcs1, the voltage of the selected bit line may be pulled up to reach the amplified voltage VA.

During the sensing operation for the row fifth activation command ACT5, the cell voltage Vc applied across the ferroelectric memory cell MC due to the amplified voltage VA for the bit line BL of the first sense amplifier 286 may reach the saturation polarization voltage Vs, and the polarization state and the polarization direction of the ferroelectric capacitor FC may be changed from the polarization direction D0 to the polarization direction D1.

According to the change of the polarization direction, the logic high “1” may be re-written to the ferroelectric memory cell MC connected to the bit line BL and the plate line PL during the sensing operation.

At a time point t23, the ferroelectric memory device 200a may receive a first write command WRITE1 together with a fifth column address cADDR5. Although not shown, the first write command WRITE1 may be received together with the data of the logic low “0.”

The first write command WRITE1 may be received by transitioning the write enable signal WE to logic low, and the fifth column address cADDR5 received together with the first write command WRITE1 may become a valid address for the write operation.

At a time point t24, the column decoder 270 may turn on the column select transistor by applying the selection voltage on the column selection line corresponding to the fifth column address cADDR5, and the bit line BL and the data line DL coupled to the column switch are electrically connected to each other.

In response to the difference between the data of the logic high “1” detected by the first sense amplifier 286 and the input data Din of the logic low “0” with respect to the first write command WRITE1, the write driver 291 may drive the voltage of the bit line BL corresponding to the fifth column address cADDR5. The write driver 291 may change the voltage of the bit line BL from the amplified voltage VA to the ground voltage Vss.

The cell voltage Vc applied across the ferroelectric memory cell MC due to the application of the ground voltage Vss for the bit line BL may reach the negative saturation polarization voltage −Vs, and the polarization state and the polarization direction of the ferroelectric capacitor FC may be changed.

According to the change of the polarization direction, the data of the logic low “0” may be written in the ferroelectric memory cell MC connected to the bit line BL and the plate line PL.

At a time point t25, the ferroelectric memory device 200a may receive a fifth precharge command PRE5 together with a fifth bank address bADDR5.

The row address strobe signal RAS and the write enable signal WE may transition to logic low, and the fifth bank address bADDR5 received together may become a valid address for the precharge operation. The fifth bank address bADDR5 may include address information of a bank in which the precharge operation is performed.

At a time point t26, upon receiving the fifth precharge command PRE5, the first sense amplifier 286 may provide the ground voltage Vss to the bit line BL in the selected bank, and the plate line voltage generator 294 may provide the ground voltage Vss to the plate line PL in the selected bank. The word line driver 311 may apply turn off voltage to the activated word line WL, and deactivate the word line WL by pulling down its voltage to the ground voltage Vss. Each of the first sense amplifier 286 and the plate line voltage generator 294 may provide the ground voltage Vss to each of the bit line BL and the plate line PL in the selected bank.

The precharge operation may be completed in a precharge period, in which the voltages of word line WL, the bit line BL, and the plate line PL are pulled down to the ground voltage Vss. At a time point t27, the ferroelectric memory device 200a may receive an eighth activation command ACT8 together with a sixth row address rADDR6.

During the charge sharing period Tcs between the time point t21 and the time point t22, the data stored in the ferroelectric memory cell MC may be lost due to the charge sharing operation, and the polarization direction of the ferroelectric capacitor FC may be reversed. Therefore, the stored data in the ferroelectric memory cell MC needs to be re-written in the ferroelectric memory cell MC.

During the sensing period Ts between the time point t22 and the time point t24, the amplification operation by the first sense amplifier 286 may be performed, in which the voltage of the bit line BL may be pulled up to the amplified voltage VA based on the stored data in the ferroelectric memory cell MC which is the logic high “1.” Because the bit line voltage is pulled up to the amplified voltage VA, the cell voltage Vc applied across the ferroelectric capacitor FC may reach the saturation polarization voltage Vs. The sensing operation and the rewrite operation, in which the polarization direction of the ferroelectric capacitor FC is changed, may be performed simultaneously.

During the sensing period Ts, due to the pull-up to the amplified voltage VA, the ferroelectric memory device 200a may simultaneously perform the sensing operation and the rewrite operation.

During a writing period Tw between the time point t24 and the time point t26 by the write driver 291, the voltage of the bit line BL may be changed from the amplified voltage VA to the ground voltage Vss. The cell voltage Vc applied across the ferroelectric capacitor FC may reach the negative saturation polarization voltage −Vs. During the writing period Tw, the write operation may change the polarization state and the polarization direction of the ferroelectric capacitor FC. Due to the voltage change of the bit line BL, the ferroelectric memory device 200a may write the data of the logic low “0” to the ferroelectric memory cell MC, immediately after the rewrite operation of writing the logic high “1” into the ferroelectric memory cell MC.

The write operation of the logic low “0” needs to be completed before the time point t26 at which precharge operation is performed. During the precharge period Tp between the time point t26 and the time point t27, the bit line BL and the plate line PL may be pulled down to the ground voltage.

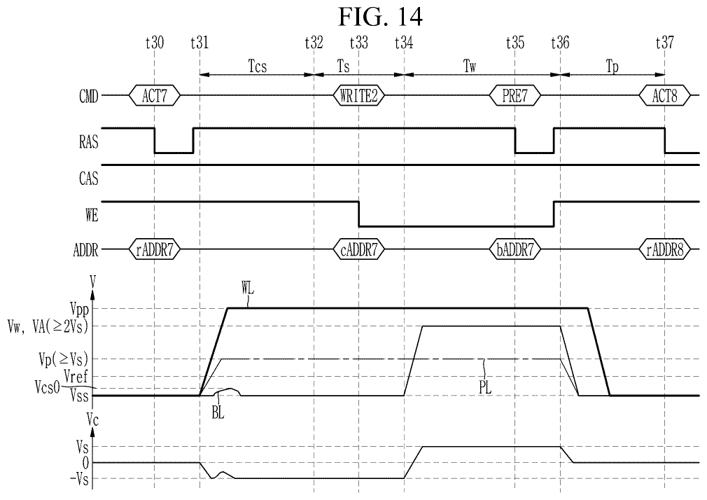

FIG. 14 is a timing diagram for explaining the write operation of the ferroelectric memory cell MC. More particularly, FIG. 14 illustrates a write operation sequence of the ferroelectric memory device 200a performed to write the data of the logic high “1” to the ferroelectric memory cell storing the data of the logic low “0.”

Referring to FIG. 2, FIG. 4, FIG. 10 and FIG. 14, during a precharge state before a time point t30, the plate line PL and the bit line BL may be precharged to the ground voltage Vss.

At the time point t30, the ferroelectric memory device 200a may receive a seventh activation command ACT7 together with a seventh row address rADDR7.

The seventh activation command ACT7 may be received by transitioning the row address strobe signal RAS to logic low, and the seventh row address rADDR7 received together may become a valid address for the activation operation. The seventh row address rADDR7 may include row information with respect to the word line WL to be selected.

At a time point t31, the row decoder 260 may activate the word line WL corresponding to the seventh row address rADDR7, and the word line driver 311 may provide the word line driving voltage Vpp to the activated word line WL. In addition, the plate line voltage generator 294 may select the plate line PL corresponding to the seventh row address rADDR7, and provide the plate line voltage Vp to the selected plate line PL.

By applying the plate line voltage Vp and the word line driving voltage Vpp to the selected word line WL and the selected plate line PL respectively, the cell voltage Vc applied across the ferroelectric capacitor FC may reach the negative saturation polarization voltage −Vs, and the polarization state of the ferroelectric capacitor FC may be changed.

As the polarization state changes, charges may be shared with the selected bit line BL. During the charge sharing, the voltage of the bit line BL connected to the ferroelectric memory cell MC may be changed from the ground voltage to the second charge sharing voltage Vcs0.

At a time point t32, the first sense amplifier 286 may detect the second charge sharing voltage Vcs0 of the bit line BL, and may compare the second charge sharing voltage Vcs0 with the reference voltage Vref, and may amplify the voltage difference between the first charge sharing voltage Vcs0 and the reference voltage Vref. Because the reference voltage Vref is preset to be higher than the second charge sharing voltage Vcs0, the voltage of the selected bit line may be pulled down to the ground voltage Vss.

During the sensing operation for the row activation command, the cell voltage Vc applied across the ferroelectric memory cell MC due to the ground voltage Vss for the bit line BL of the first sense amplifier 286 may reach the negative saturation polarization voltage −Vs, and the polarization state of the ferroelectric capacitor FC may be changed but the polarization direction may remain as polarization direction D0. Because the polarization direction is maintained, the ferroelectric memory cell MC connected to the bit line BL and the plate line PL may preserve the data of the logic low “0.”

At a time point t33, the ferroelectric memory device 200a may receive a second write command WRITE2 together with a seventh column address cADDR7. Although not shown, the second write command WRITE2 may be received together with the data of the logic high “1.”

The second write command WRITE2 may be received by transitioning the write enable signal WE to logic low, and the seventh column address cADDR7 received together with the second write command WRITE2 may become a valid address for the write operation.

At a time point t34, the column decoder 270 may turn on a column switch by applying a selection voltage the column selection line corresponding to the seventh column address cADDR7, and the bit line BL and the data line DL coupled to the column switch are electrically connected to each other.

In response to the difference between the data of the logic low “0” detected by the first sense amplifier 286 and the input data Din of the logic high “1” with respect to the second write command WRITE2, the write driver 291 may drive the voltage of the bit line BL corresponding to the seventh column address cADDR7. The write driver 291 may change the voltage of the bit line BL from the ground voltage Vss to a write voltage Vw. The write voltage Vw may be the same as the amplified voltage VA of the first sense amplifier 286.

The cell voltage Vc applied across the ferroelectric memory cell MC due to the application of the write voltage Vw for the bit line BL may reach the saturation polarization voltage Vs, and the polarization state and the polarization direction of the ferroelectric capacitor FC may be changed.

According to the change of the polarization direction, the data of the logic high “1” may be written in the ferroelectric memory cell MC connected to the bit line BL and the plate line PL.

At a time point t35, the ferroelectric memory device 200a may receive a seventh precharge command PRE7 together with a seventh bank address bADDR7.

The row address strobe signal RAS and the write enable signal WE may transition to logic low, and the seventh bank address bADDR7 received together may become a valid address for the precharge operation. The seventh bank address bADDR7 may include address information of a bank in which the precharge operation is performed.

At a time point t36, upon receiving the seventh precharge command PRE7, the first sense amplifier 286 may provide the ground voltage Vss to the bit line BL in the selected bank, and the plate line voltage generator 294 may provide the ground voltage Vss to the plate line PL in the selected bank. The word line driver 311 may apply turn off voltage to the activated word line WL, and deactivate the activated word line WL by pulling down its voltage to the ground voltage Vss. Each of the first sense amplifier 286 and the plate line voltage generator 294 may provide the ground voltage Vss to each of the bit line BL and the plate line PL in the selected bank.

After grounding the word line WL, the bit line BL, and the plate line PL, at a time point t37, the ferroelectric memory device 200a may receive the eighth activation command ACT8 together with an eighth row address rADDR8.

During the charge sharing period Tcs between the time point t31 and the time point t32, the polarization state of the ferroelectric capacitor FC may be changed but the polarization direction may be maintained.

During the sensing period Ts between the time point t32 and the time point the amplification operation by the first sense amplifier 286 may be performed, in which the voltage of the bit line BL may be pulled down to the ground voltage Vss. The cell voltage Vc applied across the ferroelectric memory cell MC may reach the negative saturation polarization voltage −Vs, and the polarization direction of the ferroelectric capacitor FC may be maintained and the data stored in the ferroelectric memory cell MC may be preserved such that data may be rewritten.

During the sensing period Ts, due to the pull-down to the ground voltage Vss, the ferroelectric memory device 200a may simultaneously perform the sensing operation and the rewrite operation.

During the writing period Tw between the time point t34 and the time point t36, by the write driver 291, the voltage of the bit line BL may be changed from the ground voltage Vss to the write voltage Vw. The cell voltage Vc applied across the ferroelectric capacitor FC may reach the saturation polarization voltage Vs During the writing period Tw, the write operation may change the polarization state and the polarization direction of the ferroelectric capacitor FC. Due to the voltage change of the bit line BL, the ferroelectric memory device 200a may write the data of the logic high “1” to the ferroelectric memory cell MC, immediately after the rewrite operation of writing the logic low “0” into the ferroelectric memory cell MC.

The write operation needs to be completed before the time point t36 at which precharge operation starts. During the precharge period Tp between the time point t36 and the time point t37, the bit line BL and the plate line PL may be pulled down to the ground voltage.

Because the cell voltage of the ferroelectric memory cell MC is changed depending on the stored data in the ferroelectric memory cell, the write operation may be performed in a branched manner depending on the data value to be stored. Some of the branched write operations may be performed in a delayed write back manner during the precharge period, in which the access time of the memory device may be increased and deteriorate the performance of the ferroelectric memory device.

According to an embodiment, a ferroelectric memory device may perform the write operation before the precharge period without a branch regardless of the data to be stored. A fixed voltage may be applied to the plate line regardless of whether the ferroelectric memory cell is accessed or not. The application of the fixed voltage to the plate line may cause an inefficient power consumption and degrade operation speed of the ferroelectric memory device.

Referring to FIG. 13 and FIG. 14, the ferroelectric memory device 200a may provide the saturation polarization voltage Vs or the negative saturation polarization voltage −Vs to the ferroelectric capacitor FC in the writing period Tw. Through provision of the saturation polarization voltage Vs or the negative saturation polarization voltage −Vs in the writing period Tw, although a voltage of plate line PL is changed depending on whether it is accessed, the ferroelectric memory device 200a may complete the write operation in the writing period Tw, regardless of the data to be stored.

The ferroelectric memory device 200a may not only improve the power consumption, but also improve the access time by completing the write operation in the writing period Tw. The ferroelectric memory device 200a may reduce the precharge period Tp and reduce the memory access time by completing the write operation before the precharge operation without branching and performing a part of the write operation in a delayed write back manner in the precharge period Tp.

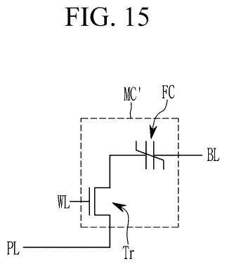

FIG. 15 is a circuit diagram showing an example of the ferroelectric memory cell of FIG. 2. A ferroelectric memory cell MC′ may correspond to the ferroelectric memory cell MC of FIG. 3.

Referring to FIG. 15, the first terminal of the cell transistor Tr in the ferroelectric memory cell MC′ may be connected to the plate line PL, and the second terminal of the cell transistor Tr may be connected to the ferroelectric capacitor FC.

The first electrode of the ferroelectric capacitor FC in the ferroelectric memory cell MC′ may be connected to the cell transistor Tr, and the second electrode of the ferroelectric capacitor FC may be connected to the bit line BL.

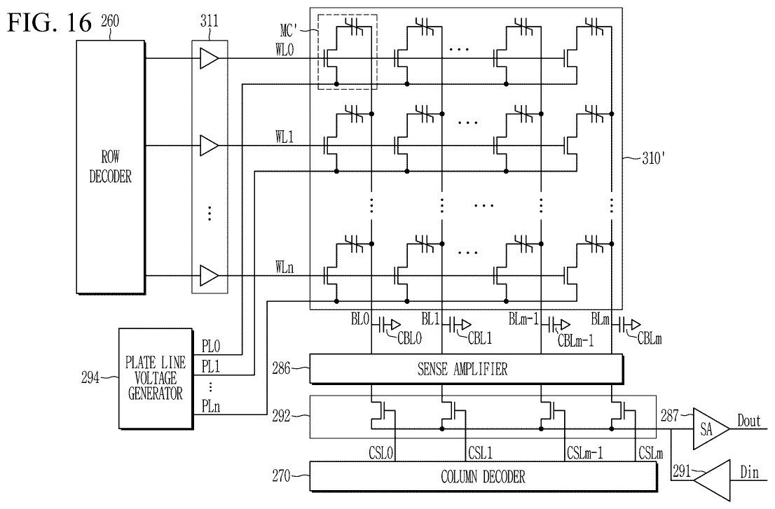

FIG. 16 is a drawing for explaining the bank array according to an embodiment. A bank array 310′ may correspond to the bank array 310 of FIG. 10.

Referring to FIG. 2, FIG. 15, and FIG. 16, the bank array 310′ may include a plurality of word lines WL0 to WLn, a plurality of bit lines BL0 to BLm, a plurality of plate lines PL0 to PLn, and a plurality of ferroelectric memory cells MC′ disposed in regions where the word lines WL0 to WLn and the bit lines BL0 to BLm intersect each other.

Each of the plurality of ferroelectric memory cells MC′ may include the cell transistor Tr and the ferroelectric capacitor FC.

The first terminal of the cell transistor Tr may be connected to the first electrode of the ferroelectric capacitor FC, and the second terminal of the cell transistor Tr may be connected to the first plate line PL0. The gate terminal of the cell transistor TR may be connected to the first word line WL0. The first terminal may be a drain terminal, and second terminal may be a source terminal, but is not limited thereto. The second electrode of the ferroelectric capacitor FC may be connected to the first bit line BL0.

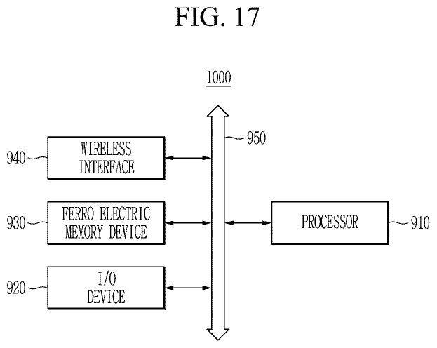

FIG. 17 is a block diagram showing an electronic device according to an embodiment.

Referring to FIG. 17, an electronic device 1000 may include a PDA, a laptop computer, a portable computer, a web tablet, a wireless phone, a mobile phone, a digital music player, a wired/wireless electronic device, etc., but is not limited thereto. The electronic device 1000 may include a processor 910, an input/output device 920 (e.g., a keypad, a keyboard and/or a display), a ferroelectric memory device 930, and a wireless interface 940. The processor 910, the input/output device 920, the ferroelectric memory device 930, and the wireless interface 940 may communicate data and commands with each other by transmitting signals through a bus 950.

The processor 910 may be implemented in a hardware-like processing circuit including logic circuits, a hardware/software combination such as a processor execution software, or a combination thereof. For example, the processor 910 may more specifically include, but is not limited to, a central processing unit (CPU), a microprocessor, a digital signal processor, a micro controller or other logic device. Other logic devices may have functions similar to those of a microprocessor, a digital signal processor, or a microcontroller. The processor 910 may incorporate a memory controller for the ferroelectric memory device 930.

The ferroelectric memory device 930 may store instructions to be executed by the processor 910. Additionally, the ferroelectric memory device 930 may also be used to store a user data. The ferroelectric memory device 930 may correspond to the ferroelectric memory device 200a of FIG. 1 to FIG. 17, and may include a plurality of ferroelectric memory cells. When performing the read operation with respect to the ferroelectric memory cell, as described above with respect to FIG. 1 to FIG. 17, the ferroelectric memory device 930 may complete the rewrite operation in the sensing period and the reading period regardless of the stored data, while changing the voltage of the plate line. In addition, when performing the write operation with respect to the ferroelectric memory cell, as described referring to FIG. 1 to FIG. 17, the ferroelectric memory device 930 may complete the write operation in the writing period regardless of the stored data, while the voltage of the plate line changes. Through this, the ferroelectric memory device 200a may not only improve the power consumption, but also improve the memory access time.

The electronic device 1000 may use the wireless interface 940 to transmit a data to or receive a data from a wireless communication network that communicates with wireless frequency (RF) signals. For example, the wireless interface 940 may include an antenna or a wireless transceiver. The electronic device 1000 can be used for communication interface protocols such as third generation communication systems (e.g., CDMA, GSM, NADC, E-TDMA, WCDMA and/or CDMA2000).

While this invention has been described in connection with practical embodiments, it is to be understood that the invention is not limited to the disclosed embodiments. various modifications and equivalent arrangements may be made without departing the spirit and scope of the appended claims.

What is claimed is:

1. A ferroelectric memory device, comprising:
a ferroelectric memory cell including a cell transistor and a ferroelectric capacitor connected in series between a bit line and a plate line, and the cell transistor connected to a word line;
a row decoder configured to activate the word line upon receiving a row activation command;
a plate line voltage generator configured to provide a ground voltage to the plate line in a precharged state, and to provide a first voltage to the plate line upon receiving the row activation command; and
a sense amplifier configured to perform a sensing operation in response to the row activation command, wherein the sense amplifier amplifies a voltage of the bit line to one of a ground voltage and a second voltage depending on stored data in the ferroelectric capacitor, in which the second voltage is higher than the first voltage.

2. The ferroelectric memory device of claim 1, wherein, the word line, the bit line and the plate line are precharged to a ground voltage in the precharged state, and the plate line voltage generator is configured to provide the first voltage to the plate line upon receiving the row activation command, in which the plate line voltage is changed from the ground voltage to the first voltage.

3. The ferroelectric memory device of claim 2, wherein, during the sensing operation, the bit line voltage is pulled down to the ground voltage when the stored data is logic low and is pulled up to the second voltage when the stored data is the logic high, and a potential of the second voltage is 2 times to 2.5 times higher than a potential of the first voltage.

4. The ferroelectric memory device of claim 3, wherein, when the first voltage is 1V, the second voltage is 2V to 2.5V.

5. The ferroelectric memory device of claim 3, wherein, the ferroelectric memory device is configured to rewrite the data stored in the ferroelectric memory cell with one of the ground voltage and the second voltage during the sensing operation.

6. The ferroelectric memory device of claim 2, wherein, the ferroelectric memory device is configured to perform a charge sharing operation before the sensing operation, during the charge sharing operation, the charge of the ferroelectric capacitor is shared with the bit line, thereby the voltage of the bit line is changed to a charge sharing voltage that is higher than a predetermined reference voltage when the data stored in the ferroelectric capacitor is logic high, and the charge sharing voltage is lower than the predetermined reference voltage when the data stored in the ferroelectric capacitor is the logic low, and during the sensing operation, and the sense amplifier is configured to amplify the charge sharing voltage of the bit line to the second voltage when the charge sharing voltage is higher than a predetermined reference voltage, and to pull down the bit line to the ground voltage when the charge sharing voltage is lower than the predetermined reference voltage.

7. The ferroelectric memory device of claim 1, wherein the ferroelectric memory cell comprises a cell transistor and a ferroelectric capacitor coupled in series between the bit line and the plate line, a first terminal of the cell transistor is connected to the bit line and a second terminal of the cell transistor is connected to a second electrode of the ferroelectric capacitor, and a first electrode of the ferroelectric capacitor is connected to the plate line.

8. The ferroelectric memory device of claim 7, wherein the ferroelectric capacitor is polarized in a first direction or in a second direction depending on whether the stored data is logic high or logic low during a precharge period, and upon receiving the row activation command and the first voltage being applied to the plate line, a polarization direction of the ferroelectric capacitor polarized in the first direction is changed to the second direction.

9. The ferroelectric memory device of claim 1, wherein the ferroelectric memory cell comprises a cell transistor and a ferroelectric capacitor connected in series between the bit line and the plate line, a first terminal of the cell transistor is connected to the plate line and a second terminal of the cell transistor is connected to a second electrode of the ferroelectric capacitor, and a first electrode of the ferroelectric capacitor is connected to the bit line.

10. A ferroelectric memory device, comprising:
a ferroelectric memory cell including a cell transistor and a ferroelectric capacitor connected in series between a bit line and a plate line, and the cell transistor connected to a word line;
a row decoder configured to activate the word line upon receiving a row activation command;
a plate line voltage generator configured to provide a first voltage to the plate line upon receiving the row activation command, and provide a ground voltage to the plate line upon receiving a precharge command; and
a sense amplifier configured to provide the ground voltage to the bit line upon receiving the precharge command.

11. The ferroelectric memory device of claim 10, wherein, during a sensing operation in response to the row activation command, the sense amplifier is configured to amplify a charge sharing voltage of the bit line to one of a ground voltage and a second voltage depending on the stored data in the ferroelectric capacitor, in which the second voltage is higher than the first voltage.

12. The ferroelectric memory device of claim 11, wherein, after a precharge operation being performed in response to the precharge command, the ferroelectric capacitor remains polarized in one of a first direction and a second direction depending on data stored in the ferroelectric capacitor, and upon receiving the row activation command and the first voltage being applied to the plate line, a polarization direction of the ferroelectric capacitor polarized in the first direction is changed to the second direction.

13. The ferroelectric memory device of claim 12, wherein the ferroelectric memory device is configured to rewrite the data stored in the ferroelectric memory cell with the ground voltage or the second voltage during the sensing operation.

14. The ferroelectric memory device of claim 11, wherein the ferroelectric memory device is configured to perform a charge sharing operation before the sensing operation upon receiving the row activation command, in which during the charge sharing operation, the charge of the ferroelectric capacitor is shared with the bit line, thereby the voltage of the bit line is changed to a charge sharing voltage that is higher than a predetermined reference voltage when the data stored in the ferroelectric capacitor is logic high, and the charge sharing voltage is lower than the predetermined reference voltage when the data stored in the ferroelectric capacitor is logic low, and during the sensing operation, the sense amplifier is configured to amplify the charge sharing voltage of the bit line to the second voltage when the charge sharing voltage is higher than a predetermined reference voltage, and to pull down the bit line to the ground voltage when the charge sharing voltage is lower than the predetermined reference voltage.

15. The ferroelectric memory device of claim 10, wherein, in response to the precharge command, the plate line voltage generator and the sense amplifier are configured to provide the ground voltage to the plate line and the bit line, after a precharge operation being performed, the ferroelectric capacitor remains as polarized in a first direction when the stored data in the ferroelectric capacitor is logic high and in a second direction when the stored data in the ferroelectric capacitor is the logic low.

16. A ferroelectric memory device, comprising:
a ferroelectric memory cell including a cell transistor and a ferroelectric capacitor connected in series between a bit line and a plate line, and the cell transistor being controlled by a word line;
a row decoder configured to activate the word line upon receiving a row activation command;
a plate line voltage generator configured to provide a first voltage to the plate line upon receiving the row activation command; and
a write driver, in response to a write command, configured to drive a voltage of the bit line to one of a ground voltage and a second voltage, in which the second voltage is higher than the first voltage.

17. The ferroelectric memory device of claim 16, further comprising:
a sense amplifier configured to perform a sensing operation in response to the row activation command, wherein the sense amplifier amplifies a voltage of the bit line to one of a ground voltage and a second voltage depending on stored data in the ferroelectric capacitor, in which the second voltage is higher than the first voltage, wherein the write driver is configured, in response to the write command, to provide one of the ground voltage or the second voltage to the bit line depending on the data to be written into the ferroelectric capacitor.

18. The ferroelectric memory device of claim 16, further comprising:
a sense amplifier configured, during a sensing operation in response to the row activation command, to change polarization direction of the ferroelectric capacitor from a first direction to a second direction when stored data in the ferroelectric capacitor is logic high,
wherein the write driver is configured, in response to the write command, to provide one of the ground voltage or the second voltage to the bit line depending on write data, thereby change the polarization direction of the ferroelectric capacitor in accordance with the write data.

19. The ferroelectric memory device of claim 18, wherein the plate line voltage generator is configured to provide the ground voltage to the plate line in response to a precharge command, and the sense amplifier is configured to provide the ground voltage to the bit line in response to the precharge command.

20. The ferroelectric memory device of claim 19, wherein the write driver is configured to drive the voltage of the bit line based on the write data, and change the polarization direction of the ferroelectric capacitor when the write data with respect to the write command is different from the stored data in the ferroelectric memory cell.
